(19) United States
(12) Patent Application Publication
(10) Pub. No.: US 2026/0324395 A1
(43) Pub. Date: Oct. 15, 2026

(54) SEMICONDUCTOR DEVICE AND METHOD OF MANUFACTURING SEMICONDUCTOR DEVICE

(71) Applicant: Taiwan Semiconductor Manufacturing Company, Ltd., Hsinchu (TW)

(72) Inventors: Chia-Pang KUO, Taoyuan (TW); Kuei-Wen HUANG, Hsinchu (TW); Ming-Uei HUNG, Taichung (TW); Chih-Han TSENG, Tainan (TW); Kan-Ju LIN, Kaohsiung (TW); Ya-Lien LEE, Baoshan Township (TW)

(73) Assignee: Taiwan Semiconductor Manufacturing Company, Ltd., Hsinchu (TW)

(21) Appl. No.: 19/342,261

(22) Filed: Sep. 26, 2025

Related U.S. Application Data
(60) Provisional application No. 63/788,745, filed on Apr. 14, 2025.

(51) Int. Cl. H10W 20/42; H10W 20/00; H10W 20/40; H10W 20/41; H10W 20/44

(52) U.S. Cl. CPC H10W 20/422; H10W 20/035; H10W 20/056; H10W 20/062; H10W 20/066; H10W 20/092; H10W 20/435; H10W 20/4424; H10W 20/4441; H10W 20/498

(57) ABSTRACT

According to various embodiments, a method of manufacturing a semiconductor device includes performing processing operations to form an interconnect structure over a plurality of transistors, such that the interconnect structure includes a plurality of dielectric layers interleaved by a plurality of etch stop layers, and the interconnect structure includes a plurality of metal lines disposed in the plurality of dielectric layers. The processing operations include forming a second dielectric layer, including a first opening, over a first dielectric layer, depositing a first conductive material in the first opening to form a conductive contact via, exposing the conductive contact via to a silicon-containing gas, forming a third dielectric layer, including a second opening, over the conductive contact via and the second dielectric layer, and depositing a second conductive material in the second opening to form a metal line.

### CROSS-REFERENCE TO RELATED APPLICATION

This application claims priority to U.S. Provisional Patent Application No. 63/788,745, filed on Apr. 14, 2025, the disclosure of which is incorporated herein by reference in its entirety.

### BACKGROUND

The semiconductor industry continues to advance by increasing the integration density of electronic components such as transistors, diodes, resistors, inductors, and capacitors. Manufacturers have traditionally achieved this scaling by successively reducing the minimum feature size, thereby incorporating greater functionality within a fixed chip area. As critical dimensions decrease, however, the design and fabrication of transistors, interconnects, and related structures grow increasingly complex. In particular, continued scaling introduces challenges related to the development of new materials, process technologies, and device architectures that support reliable and efficient electrical connections at ever-smaller scales. These challenges include, among others, controlling contact interfaces to reduce contact resistance and enhance electrical conductivity, as well as minimizing undesirable material interactions that can degrade device performance.

### BRIEF DESCRIPTION OF THE DRAWINGS

The present disclosure is best understood from the following detailed description when read with the accompanying figures. It is emphasized that, per the standard practice in the industry, various features are not drawn to scale and are used for illustration purposes only. The dimensions of the various features may be arbitrarily increased or reduced for clarity of discussion.

FIG. 1A is a vertical cross-sectional view of a semiconductor device structure including an electrical contact that includes a conductive contact via and a metal line, according to various embodiments.

FIG. 1B is a vertical cross-sectional view of a portion of the semiconductor device of FIG. 1A, according to various embodiments.

FIG. 2A is a vertical cross-sectional view of a structure having a silicon-rich layer formed at interfaces of the electrical contact, according to various embodiments.

FIG. 2B is a vertical cross-sectional view of a structure having metal silicide layers formed at interfaces of the electrical contact, according to various embodiments.

FIG. 3 is a table showing various chemical precursor materials used to form the metal silicide layers, according to various embodiments.

FIG. 4 illustrates chemical reactions between silicon-based precursor chemicals and metal interfaces to form metal silicide layers, according to various embodiments.

FIG. 5 is a process flow diagram indicating operations of a process of forming metal silicide layers at interfaces of an electrical contact, according to various embodiments.

FIG. 6 is a process flow diagram indicating operations of a process of forming metal silicide layers at interfaces of an electrical contact, according to various embodiments.

FIG. 7 is a table comparing three example structures formed using the fabrication processes described with references to FIGS. 5 and 6, according to various embodiments.

FIG. 8 is a flowchart of operations of a method of manufacturing a semiconductor device, according to various embodiments.

FIG. 9 is a flowchart of operations of a method of manufacturing a semiconductor device, according to various embodiments.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values but may depend upon process conditions and/or desired properties of the device. Moreover, the formation of a first feature over or on a second feature in the description that follows include embodiments in which the first and second features are formed in direct contact, and may also include embodiments in which additional features may be formed by interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” or the like, may be used herein for ease of description to describe one element or feature's relationship to another element(s) or feature(s) as illustrated in the figures. The spatially relative terms are intended to encompass different orientations of the device in use or operation, in addition to the orientation depicted in the figures. The apparatus may be otherwise oriented (rotated 90 degrees or at other orientations), and the spatially relative descriptors used herein may likewise be interpreted accordingly. In addition, the term “made of” may mean either “comprising” or “consisting of.” In the present disclosure, the phrase “one of A, B and C” means “A, B and/or C” (A, B, C, A and B, A and C, B and C, or A, B and C), and does not mean one element from A, one element from B and one element from C, unless otherwise described.

As semiconductor devices scale to smaller dimensions, the stability and reliability of interconnect structures play an ever-increasing role in overall device performance. These interconnects, which electrically couple various components within a semiconductor device, should maintain their integrity over time and operate reliably under a range of thermal and electrical conditions. Among the challenges in this context is the control of material interactions at interfaces between conductive and dielectric layers.

In particular, the diffusion of conductive materials—such as copper—along interfaces and into adjacent dielectric regions can lead to degradation of the interconnect structure. This diffusion tends to compromise the electrical and mechanical properties of the interfacial region, potentially resulting in increased contact resistance, reduced current-carrying capability, short circuits, and long-term reliability concerns. Disclosed embodiments address these issues by providing improved interconnect designs and materials systems that suppress undesirable diffusion, thereby showing promise in extending the useful lifetime during which interconnects maintain stable electrical performance.

Disclosed embodiments advantageously provide conductive contacts that exhibit reduced contact resistance and reduced undesirable material interactions that could otherwise degrade device performance. In this regard, disclosed electrical contacts include metal-silicide layers formed at metal/metal and metal/dielectric interfaces. The presence of the metal-silicide layers advantageously prevents diffusion of conductive materials and ensures a low contact resistance between metal/metal interfaces.

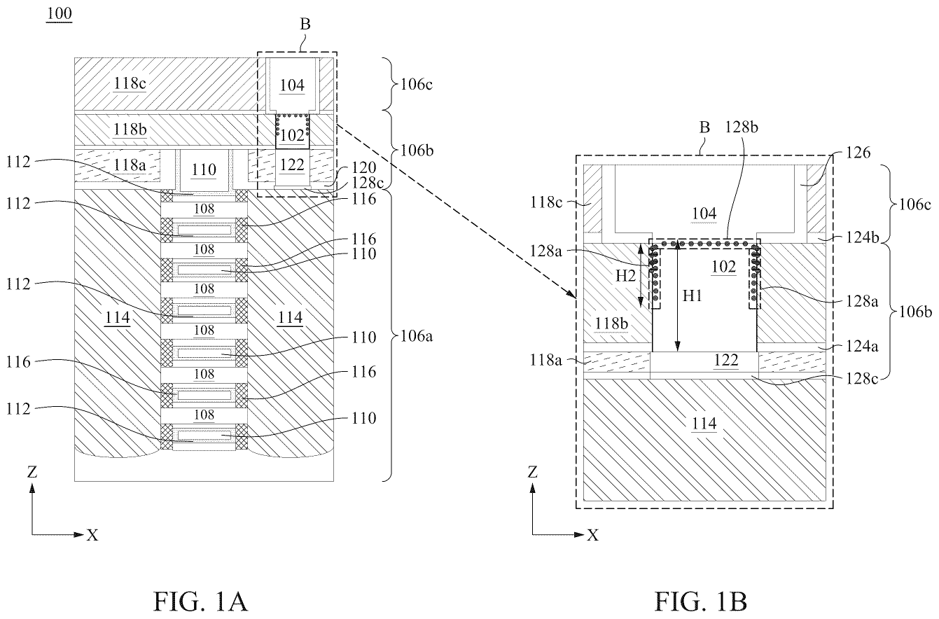

FIG. 1A is a vertical cross-sectional view of a semiconductor device structure 100 including a conductive contact via 102 that connects to a metal line 104, and FIG. 1B is an enlarged view of a portion B of the semiconductor device structure 100, including the conductive contact via 102 and the metal line 104, according to various embodiments. The semiconductor device structure 100 includes a first device portion 106a that is formed in a series of front-end-of-line (FEOL) processes, a second device portion 106b that is formed in a series of middle-end-of-line (MEOL) processes, and a third device portion 106c that is formed in a series of back-end-of-line (BEOL) processes.

The first device portion 106a is configured as a gate-all-around (GAA) transistor, and includes a plurality of semiconductor layers stacked along a thickness direction (i.e., the z-direction) and configured as stacked channel regions 108. Although six stacked channel regions 108 are shown in the embodiment of FIG. 1A, the disclosure is not so limited, and various numbers of channel regions≥1 (e.g., one channel region 108, two channel regions 108, three channel regions 108, and the like) are possible in other embodiments. This embodiment, including a GAA transistor, is provided merely as an example, and various other semiconductor devices (e.g., planar field effect transistors (FETs), fin field effect transistors (FinFETs), complementary field-effect transistors (CFETs), and the like) are provided in other embodiments.

The first device portion 106a further includes a gate structure 110 surrounding each of the stacked channel regions 108. The gate structure 110 includes an electrically conductive material that is separated from the stacked channel regions 108 by a gate dielectric layer 112. The first device portion 106a further includes source/drain epitaxial layers 114 formed on opposite ends of the stacked channel regions 108 along a width direction (i.e., the x-direction) and a plurality of dielectric spacers 116 that electrically separate the gate structure 110 from the source/drain epitaxial layers 114. A first interlayer dielectric (ILD) layer 118a is formed over the source/drain epitaxial layers 114, and a contact etch stop layer 120 is formed between the source/drain epitaxial layers 114 and the first ILD layer 118a. A source/drain contact 122 is formed in the first ILD layer 118a. The source/drain contact 122 penetrates through the contact etch stop layer 120 and forms an electrically conducting contact with the source/drain epitaxial layers 114. The conductive contact via 102 forms an electrically conducting contact with the source/drain contact 122 and with the metal line 104, as described in greater detail with reference to FIG. 1B.

Referring to FIG. 1B, the conductive contact via 102 is formed within a second ILD layer 118b that is formed over the first ILD layer 118a. A first etch stop layer 124a is formed between the first ILD layer 118a and the second ILD layer 118b. The metal line 104 is formed in a third ILD layer 118c that is formed over the second ILD layer 118b, and a second etch stop layer 124b is formed between the second ILD layer 118b and the third ILD layer 118c. At least one of the conductive contact via 102 and the metal line 104 includes a metallic fill material, such as at least one of Mo, W, Ru, Al, Au, Ag, Cu, Mn, Ni, Fe, Pt, Ta, Nb, Zr, Re, Ir, and alloys thereof. For example, in the embodiment of FIG. 1B, the conductive contact via 102 includes W, Mo, or Ru, and the metal line 104 includes Cu. These conductive materials are provided merely as examples, and other conductive materials are possible in other embodiments. In certain embodiments, the conductive contact via 102 does not include a barrier layer, and the metal line 104 includes a barrier layer 126 that at least covers sidewalls of the metallic fill material.

Referring to FIG. 1B, the conductive contact via 102 is formed within a second ILD layer 118b that is formed over the first ILD layer 118a. A first etch stop layer 124a is formed between the first ILD layer 118a and the second ILD layer 118b. The metal line 104 is formed in a third ILD layer 118c that is formed over the second ILD layer 118b, and a second etch stop layer 124b is formed between the second ILD layer 118b and the third ILD layer 118c. Each of the conductive contact via 102 and the metal line 104 includes a metallic fill material, such as at least one of Mo, W, Ru, Al, Au, Ag, Cu, Mn, Ni, Fe, Pt, Ta, Nb, Zr, Re, Ir, and alloys thereof. For example, in the embodiment of FIG. 1B, the conductive contact via 102 includes W, Mo, or Ru, and the metal line 104 includes Cu. These conductive materials are provided merely as examples, and other conductive materials are possible in other embodiments.

In some embodiments, the first ILD layer 118a, the second ILD layer 118b, and the third ILD layer 118c are made of a silicon oxide, a silicon nitride, a silicon oxynitride (SiON), SiOCN, SiCN, a fluorine-doped silicate glass (FSG), or a low-k dielectric material, formed by low pressure CVD (LPCVD), plasma-enhanced CVD (PECVD), PVD, ALD, flowable CVD, or any suitable technique. In some embodiments, the etch stop layers (124a, 124b) and the IDL layers (118a, 118b, 118c) are made of different materials. In some embodiments, the etch stop layers (124a, 124b) are made of a nitride, such as a silicon nitride, a titanium nitride, or a tantalum nitride. The etch stop layers (124a, 124b) may be formed by atomic layer deposition (ALD), physical vapor deposition (PVD), chemical vapor deposition (CVD), e-beam evaporation, or any other suitable technique. In some embodiments, the etch stop layers (124a, 124b) have a thickness ranging from about 5 nm to about 40 nm, and from about 10 nm to about 20 nm in other embodiments.

The metal line 104 further includes a barrier layer 126 formed between the Cu metallic fill material and the third ILD layer 118c, but there is no barrier layer formed between the conductive contact via 102 and the metal line 104. Rather, as shown in FIG. 1B, the semiconductor device structure 100a includes metal silicide layers (128a, 128b), including first metal-silicide layers 128a formed at interfaces between the conductive contact via 102 and the second ILD layer 118b, and a second metal-silicide layer 128b formed at an interface between the conductive contact via 102 and the metal line 104. The presence of the metal silicide layer (128a, 128b) advantageously prevents Cu diffusion and ensures a low contact resistance between the conductive contact via 102 and the metal line 104. According to certain embodiments, a third metal-silicide layer 128c is formed at an interface between the source/drain contact 122 and the source/drain epitaxial layers 114.

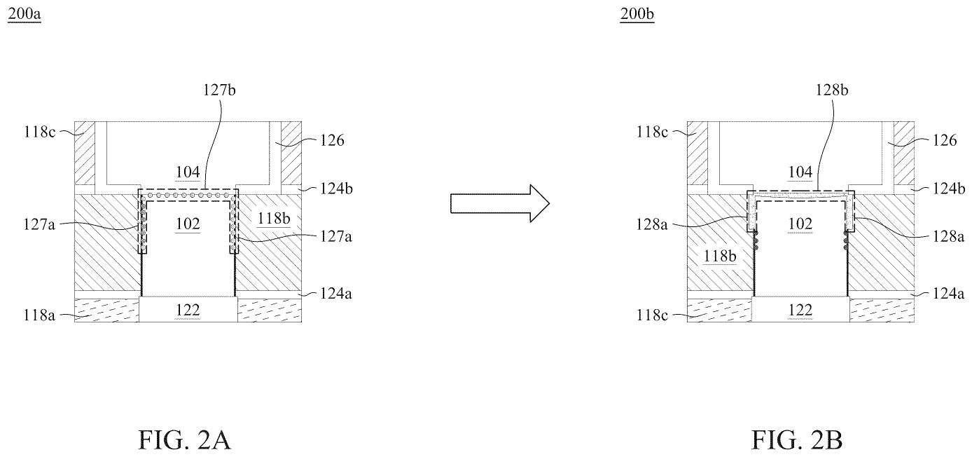

FIG. 2A is a vertical cross-sectional view of a first structure 200a having a silicon-rich layer (127a, 172b) formed at interfaces of the conductive contact via 102, and FIG. 2B is a vertical cross-sectional view of a second structure 200b having a metal silicide layer (128a, 128b) formed at interfaces of the conductive contact via 102, according to various embodiments. According to certain embodiments, the metal silicide layer 128a extends to a depth of between about 1 nm to about 8 nm, and a depth of the conductive contact via 102 extends to between about 80 nm to about 120 nm. In some embodiments, a ratio of the depth H2 of the metal silicide layer to a depth H1 of the conductive contact via 102 (H2/H1) ranges from about 0.01 to about 0.1.

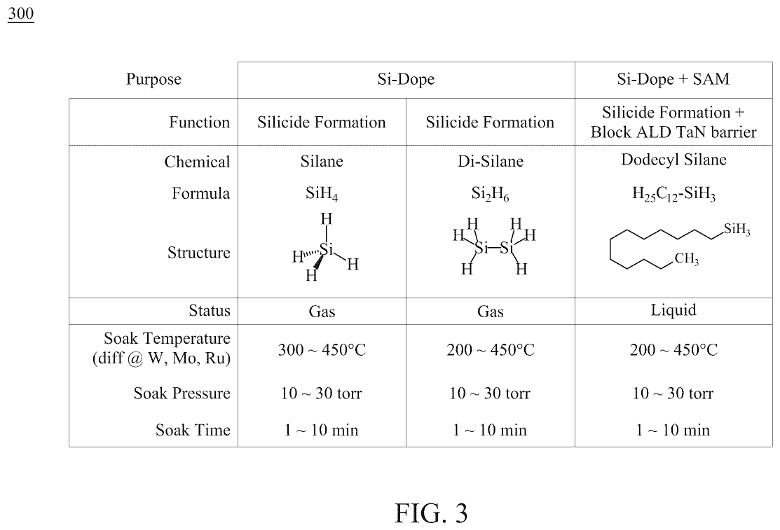

As described in greater detail below, the silicon-rich layer (127a, 172b) is formed after deposition of the conductive material that forms the conductive contact via 102 but before deposition of the conductive material that forms the metal line 104. The second structure 200b of FIG. 2B is then formed from the first structure 200a of FIG. 2A by further processing operations that are conducted at elevated temperatures. In this regard, chemical reactions occur at elevated temperatures, such as during an annealing process or further high-temperature deposition processes, which cause the formation of the metal silicid5e layers (128a, 128b) of FIG. 2B, as described in greater detail with reference to FIG. 3.

In some embodiments, a soaking operation is performed in which a silicon-containing gas is introduced at a temperature between about 200 °C and about 500 °C, at a pressure between about 1 torr to about 30 torr for about 30 seconds to about 20 minutes, such that the silicon-containing gas is applied to an exposed surface of the conductive contact via 102. In some embodiments, the silicon-containing gas is at least one selected from silane (SiH₄), di-silane (Si₂H₆), tri-silane (Si₃H₈), or tetra-silane (Si₄H₁₀), etc.

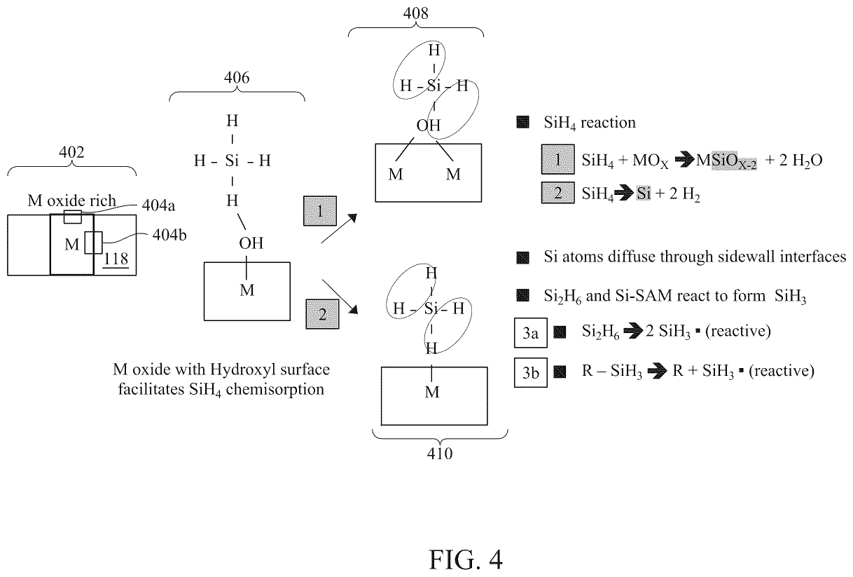

FIG. 3 is a table 300 showing examples of various chemical precursor materials for form the metal silicide layers (128a, 128b) of FIGS. 1A, 1B, and 2B, according to various embodiments. In this regard, according to certain embodiments, the silicon-rich layer (127a, 172b) is formed by exposing the conductive contact via 102 to silane, including silane (SiH₄), di-silane (Si₂H₆), tri-silane (Si₃H₈), tetra-silane (Si₄H₁₀), etc. at elevated temperature and pressure before forming the metal line 104. For example, according to some embodiments, a soaking operation is performed in which silane gas is introduced at a temperature between about 300 °C and about 450 °C, at a pressure between about 10 torr to about 30 torr for about 1 to about 10 minutes, such that a top or exposed surface of the conductive contact via 102 is exposed to the heated silane gas. In other embodiments, a soaking operation is performed in which di-silane gas is introduced at a temperature between about 200 °C and about 450 °C, at a pressure between about 10 torr to about 30 torr for about 1 to about 10 minutes, such that the top surface of the conductive contact via 102 is exposed to the heated di-silane gas. The silicon-containing gas molecules then interact with the conductive material of the conductive contact via 102 and are thereby chemisorbed to the surface of the conductive contact via 102. Further chemical reactions then occur that generate the metal silicide layers (128a, 128b), as described in greater detail with reference to FIG. 4 below.

In other embodiments, the silicon-rich layer (127a, 172b) is formed by exposing the conductive contact via 102 to dodecyl silane (H₂₅C₁₂—SiH₃). In these embodiments, dodecyl silane is introduced as a liquid at a temperature between about 100 °C and about 500 °C, at a pressure between about 1 torr to about 100 torr for about 30 seconds to about 20 minutes, such that the top surface of the 102 is exposed to the heated dodecyl silane liquid. In other embodiments, the dodecyl silane is introduced as a liquid at a temperature between about 200 °C and about 450 °C, at a pressure between about 10 torr to about 30 torr for about 1 minute to about 10 minutes, as shown in FIG. 3. According to various embodiments, exposure to dodecyl silane generates a silicon-rich self-assembled monolayer (SAM) on the surface of the conductive contact via 102. Further chemical reactions then occur that generate the metal silicide layers (128a, 128b), as described in greater detail with reference to FIG. 4 below.

FIG. 4 illustrates chemical reactions between silicon-based precursor chemicals and metal interfaces to form metal silicide layers (128a, 128b), according to various embodiments. In a first configuration 402, a conductive material M is formed within a dielectric layer 118. According to an embodiment, the conductive material M is one of W, Mo, or Ru. These metals form metal/oxide-rich surfaces so that the conductive material M has a first oxide-rich surface 404a and a second oxide-rich interface 404b. The first oxide-rich surface 404a is a surface that is exposed to the silane (e.g. silane, di-silane, or dodecyl silane) during the soaking operations described above with reference to FIG. 3. Exposure to the silicon-based precursor chemicals at elevated temperature causes various chemical reactions to occur.

For example, in configuration 406, a silane molecule SiH₄ interacts with a hydroxyl group M—OH, leading to one of two reactions (1, 2). According to reaction (1), a metal silicide MSiOₓ₋₂ (with x≥2)is formed along with the release of two water molecules, as indicated by configuration 408. Alternatively, as indicated by configuration 410, silane molecules SiH₄ become bonded to the surface of the conducting material M and, according to reaction (2), a silicon atom is liberated along with two molecules of hydrogen. The free silicon atoms diffuse along the interfaces (402a, 402b) and interact with metal atoms to form the silicide layers (128a, 128b). For example, according to certain embodiments, a silicon atom reacts with copper to form a copper-silicon compound CuSiₓ, in which “x” refers to a number of silicon atoms that combine with each Cu atom, with “x” in a range from about 0.2 to about 2.0.

Various other reactions occur between the surface of the conductive material M and the silicon-based precursor chemicals when the conducting material M is treated with a different silane, such as di-silane or dodecyl silane, as indicated by chemical reactions (3a) and (3b). In this regard, when the conductive material M is treated with di-silane or dodecyl silane (e.g., forming a self-assembled monolayer), molecules of SiH₃ are formed. For example, chemical reaction (3a) indicates the formation of SiH₃ from di-silane, and chemical reaction (3b) indicates the formation of SiH₃ from dodecyl silane. In both reactions (3a, 3b), the resulting SiH₃ molecules are reactive species that interact with metal atoms of the conductive material M to form the metal silicide layers (128a, 128b), which include various compounds such as MSiOₓ, MSiₓ, CuSiₓ, and the like. According to various embodiments, metal-silicide layers (128a, 128b) exhibit volume expansion, which provides a mechanical barrier to metal atom diffusion.

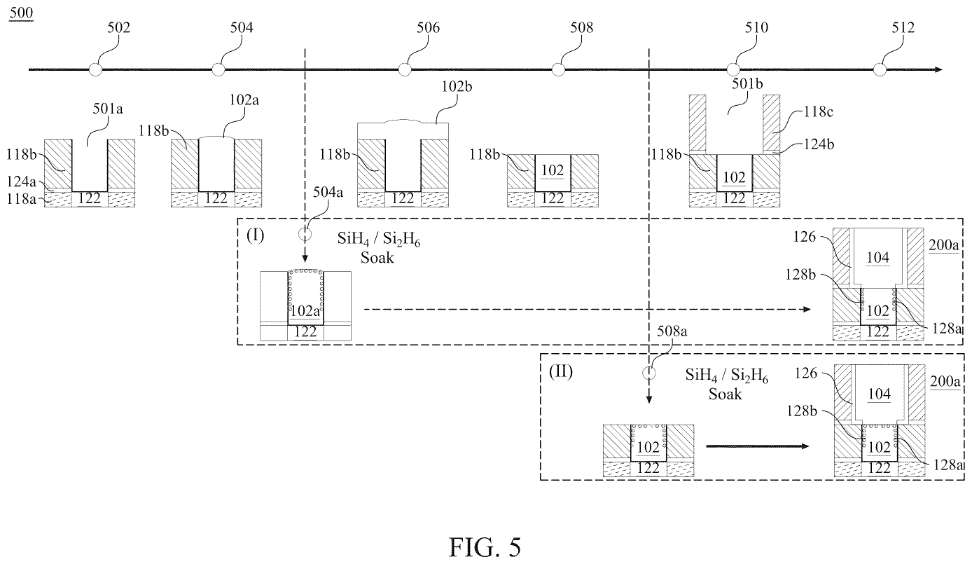

FIG. 5 is a process flow diagram 500 indicating operations of a process of forming metal silicide layers (128a, 128b) at interfaces of a conductive contact via 102, according to various embodiments. In operation 502, an anisotropic etch operation is performed to generate a first opening 501a in the second dielectric layer 118a. In operation 504, a conductive material 102a is deposited in the opening 501. According to a first alternative process flow (I), in optional operation 504a, a soaking operation is performed in which silicon-based precursor chemicals (e.g., silane or di-silane) are introduced at elevated temperature and pressure to generate the silicon-rich layers (127a, 127b), as described above with reference to FIGS. 3 and 4. Alternatively, according to a second alternative process flow (II), the soaking operation is delayed until after additional process operations (506, 508) are performed.

In operation 506, additional conductive material 102b is deposited over the conductive material 102b, which was deposited in operation 504, and over top surfaces of the second ILD layer 118b. In operation 508, a planarization process (e.g., chemical mechanical planarization (CMP)) is performed to remove a top portion of the conductive material 102b, a top portion of the second ILD layer 118a, and a top portion of the conductive material 102a that was deposited in operation 504 in some embodiments. The planarization process, performed in operation 508, creates a planar top surface to the conductive contact via 102 that is essentially level with a top surface of the second dielectric layer 118a. According to a first alternative process flow (I), the top silicide layer on the conductive contact via is removed by the CMP process and in the second alternative process flow (II), the silicide layer remains on the top surface of the conductive contact via 102.

Additional process operations (510, 512) are then performed according to both alternative process flows (I, II). In this regard, according to operation 510, a second etch stop layer 124b is deposited over the planarized surface of the second ILD layer 118b and the conductive contact via 102, and a third ILD layer 118c is deposited over the second etch stop layer 124b. An anisotropic etch process is then performed to generate a second opening 501b in the third ILD layer 118c. In operation 512, the metal line 104 is then formed in the opening 501 in the third ILD layer 118c. In this regard, the metal line 104 is formed by depositing a metallic liner layer that includes one of TiN, TaN, WN, TiC, TaC, and WC and a metallic fill material such as Cu. Various other metallic fill materials, such as Mo, W, Ru, Al, Au, Ag, Mn, Ni, Fe, Pt, Ta, Nb, Zr, Re, Ir, and alloys thereof are possible in other embodiments. In some embodiments, a Cu seed layer is first deposited by physical vapor deposition (PVD), followed by electrochemical plating (ECP) deposition of a Cu fill layer. In some embodiments, the PVD process is followed by an annealing operation at a temperature below about 200 °C, and the ECP deposition is followed by an annealing operation at a temperature above about 200 °C

Metal-silicide compounds are formed due to reactions that occur at elevated temperatures, either during a further annealing operation or at the elevated temperatures associated with the deposition processes performed in forming the metal line 104. According to various embodiments, metal-silicide compounds are formed by interaction of the silicon-rich layers (127a, 127b) with either or both of the metal material of the conductive contact via 102 and the metal line 104. As mentioned above, some metal-silicide layers (128a, 128b) exhibit volume expansion, which provides a mechanical barrier to metal atom diffusion. For example, the metal-silicide compound Cu₅Si has a density of about 7.8 g/cm³, which is a lower density than that of Cu, which is about 8.96 g/cm³. Thus, the reduced density of Cu₅Si relative to that of Cu corresponds to a volume expansion upon formation of the metal-silicide compound.

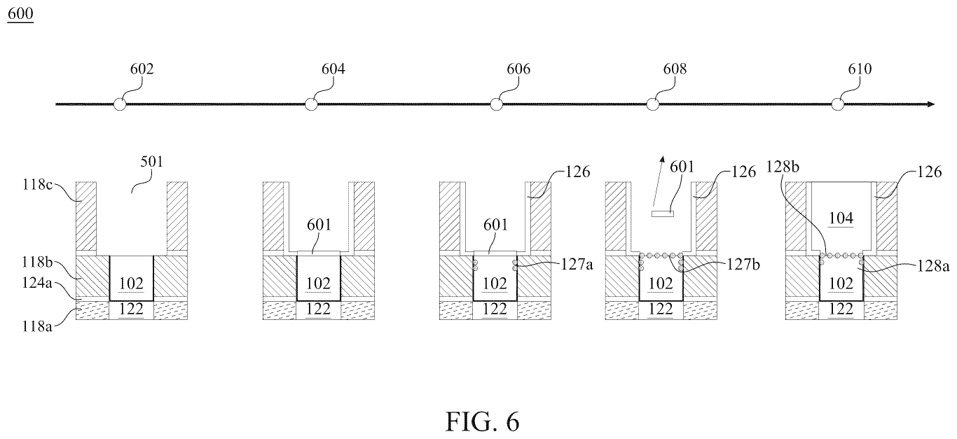

FIG. 6 is a process flow diagram 600 indicating operations of a process of forming metal silicide layers (128a, 128b) at interfaces of a conductive contact via 102, according to various embodiments. Operation 602 includes performing operations similar to those of process flow diagram 500 of FIG. 5, including operations 502, 504, 506, 508, and 510, and omitting optional operations (504a, 508a) of the process flow diagram 500 of FIG. 5. As such, the structure formed in operation 602 is equivalent to the structure formed in operation 510 if neither of the soaking operations (504a, 508a) of the alternative process flows (I, II) are performed. In operation 604, the surface of the conductive contact via 102 is exposed to dodecyl silane at elevated temperature, as described above with reference to FIGS. 3 and 4. Operation 604 thereby creates a silicon-containing layer 601 that is formed over the exposed surface of the conductive contact via 102. According to some embodiments, the silicon-containing layer 601 is a self-assembled monolayer of silicon-containing components that interact with the conductive material of the conductive contact via 102.

In operation 606, a barrier layer 126 is formed over surfaces of the third dielectric layer 118c within the opening 501. According to various embodiments, the barrier layer 126 is a metallic liner layer that includes one of Ti, Ta, TiN, TaN, WN, TiC, TaC, and WC. The barrier layer 126 is deposited using various techniques, such as by atomic layer deposition (ALD) and chemical vapor deposition (CVD). The deposition of the barrier layer 126 is carried out at an elevated temperature. For example, during ALD deposition of the barrier layer 126, the structure is raised to a temperature between about 100 °C and about 500 °C, according to certain embodiments, and between about 150 °C and about 350 °C in other embodiments As described above with reference to FIG. 3, such elevated temperatures are sufficient to cause chemical reactions between the silicon-containing layer 601 and the conductive material of the conductive contact via 102. Such reactions begin the process of formation of the silicon-rich layers (127a, 127b) that give rise to the metal silicide layers (128a, 128b) described above with reference to FIGS. 1B to 2B.

In operation 608, a plasma etch process is performed to remove the remaining silicon-containing layer 601. For example, in some embodiments, an H₂ plasma etch process is performed to remove the silicon-containing layer 601. In operation 610, the metal line 104 is formed by depositing a conductive fill material over the surfaces of the conductive contact via 102 and the barrier layer 126. According to various embodiments, the metallic fill material is Cu, although various other metallic fill materials, such as W, Al, Co, Ru, Mo, Ta, Ti, TiN, alloys thereof, and/or combinations thereof, are possible in other embodiments. According to some embodiments, one or more additional liner layers are formed between the barrier layer 126 and the metallic fill material. For example, in some embodiments, a liner layer including Co is formed between the barrier layer 126 and metallic fill material. This disclosure, however, is not so limited, and other liner materials are possible in other embodiments.

Removal of the silicon-containing layer 601 in operation 608 allows the conductive fill material, deposited in operation 610, to come in contact with the second silicon-rich layer 127b formed on the top surface of the conductive contact via 102. One or more additional heat treatments are then applied in certain embodiments to allow further chemical reactions to occur between the conductive materials of the conductive contact via 102, the metal line 104, and the silicon-rich layers (127a, 127b) to thereby form the metal silicide layers (128a, 128b), described above with reference to FIGS. 1B and 2B. For example, in some embodiments a copper silicide and a tungsten silicide is formed at the interface between the conductive contact via 102 and the metal line 104.

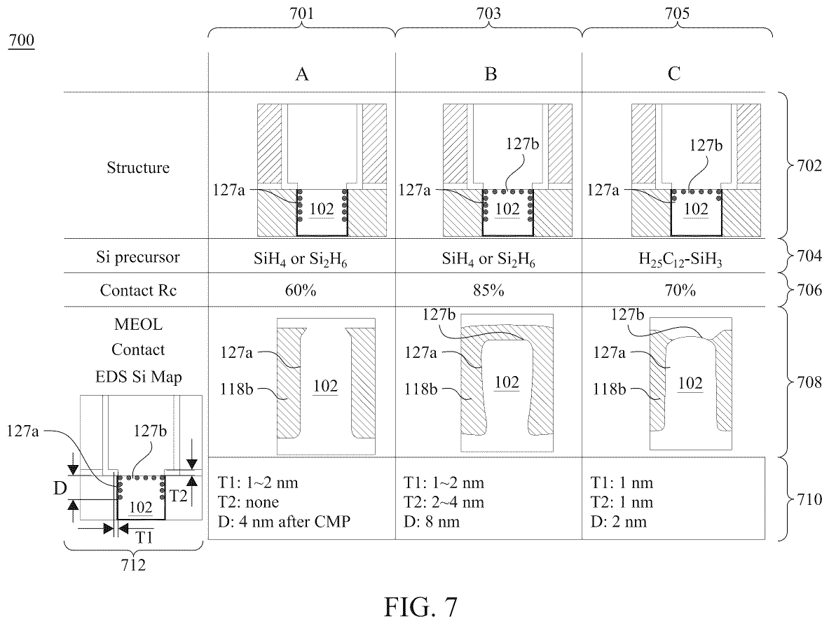

FIG. 7 is a table 700 that compares three example structures (A, B, C) formed using the fabrication processes described with references to FIGS. 5 and 6, according to various embodiments. Columns (701, 703, 705) correspond to the three example structures (A, B, C), and rows (702, 704, 706, 708, 710) provide various information related to the example structures (A, B, C). In this regard, row 702 includes models that indicate structural details of the example structures (A, B, C), and row 704 specifies the silicon-containing precursor materials used to form the silicon-rich layers (127a, 127b). Row 706 indicates measured contact resistance values that are expressed as percentages of a resistance measured for a reference structure, according to a comparative embodiment. The reference structure does not include silicon-rich layers (127a, 127b), but rather, includes a barrier layer formed between the conductive contact via 102 and the metal line 104. Row 708 presents contour maps of silicon regions measured by energy-dispersive X-ray spectroscopy (EDS). Row 710 provides dimensions of silicon-rich layers (127a, 127b) and/or metal-silicide layers (128a, 128b), and the configuration labeled 712 defines the geometric parameters (D, T1, T2) listed in row 710.

The EDS measurements shown in row 708 indicate that each of the structures (A, B, C) includes first silicon-rich layers 127a formed between the metallic fill material of conductive contact via 102 and the third ILD layer 118b, but only the second and third structures (B, C) include second silicon-rich layers 127b formed at an interface between the conductive contact via 102 and the metal line 104. In this regard, example structure A is formed according to the process flow diagram 500, following the first alternative process flow (I) that includes the optional process operation 504a. According to the first alternative process flow (I), the structure formed in operation 504 is subjected to optional operation 504a, in which a soaking operation is performed before the planarization operation 508. As such, the second silicon-rich layer 127b, which is formed on the top surface of the conductive material 102a, is removed by the planarization operation 508.

In contrast, in both the second and third structures (B, C), the silicon-containing precursor materials (e.g., di-silane and/or dodecyl silane) are introduced after the planarization process that is conducted in operation 508 of the process flow diagram 500 of FIG. 5. As such, the second silicon-rich layer 127b is formed based either on the soaking operation 508a of the second alternative process flow (II) in the formation of the example structure B, or in the process operation 601 of the process flow diagram 600 of FIG. 6 in the formation of the example structure C.

As indicated in the configuration 712 of FIG. 7, each of the first silicon-rich layers 127a extends to a depth D below a surface of the conductive contact via 102 and has a thickness T1. According to certain embodiments, the first silicon-rich layers 127a have a relatively uniform concentration as a function of depth below the surface of the conductive contact via 102. In other embodiments, the first silicon-rich layers 127a have a silicon concentration gradient along the conductive contact via 102 that decreases from a top of the conductive contact via 102 to a bottom of the conductive contact via 102. In other embodiments, the second dielectric layer 118b is doped with a concentration of silicon that decreases in a direction away from the top of the conductive contact via 102.

The second silicon-rich layers 127b (e.g., in example structures (B, C)) have a thickness T2. As indicated in row 710 of Table 700, each of the example structures (A, B, C) has a first silicon-rich layer 127a that extends to a depth D that is between about 1 nm and about 8 nm, and has a thickness T1 that is between about 1 nm and about 2 nm. The second silicon-rich layers 127b of structures (B, C) have a thickness T2 that is between about 1 nm and about 2 nm. The values of these geometric parameters (D, T1, T2) are only provided as examples obtained from the example structures (A, B, C), and other parameter values are possible in other embodiments.

According to various embodiments, each of the geometric parameters (D, T1, T2) will have an optimum value that is a tradeoff between having sufficient depth (D) and thickness (T1, T2) to prevent Cu diffusion, while keeping the depth (D) and thickness (T1, T2) as small as possible to keep a corresponding contact resistance as small as possible.

As indicated in row 706, each of the example structure (A, B, C) show improvement in that the measured contact resistance Rc is less than that of the reference structure of the comparative embodiment that does not include the silicon-rich layers (127a, 127b) and includes a barrier layer between the conductive contact via 102 and the metal line 104. These results, however, should not be interpreted as limiting, and other results, some with even greater improvement in measured contact resistance Rc, are possible in other embodiments.

High-Temperature Operating Life (HTOL) testing was performed on the example structures (A, B, C) to evaluate the long-term reliability of these structures. HTOL is an accelerated stress test that simulates extended operational lifetimes by exposing structures to elevated temperatures, voltages, and electrical bias conditions over a condensed time period. Per Joint Electron Device Engineering Council (JEDEC) standard protocols, the example structures (A, B, C) were subjected to high-temperature conditions of approximately 125 °C and biased at elevated voltages to accelerate failure mechanisms relevant to interconnects, such as electromigration and time-dependent dielectric breakdown (TDDB). The test was conducted over 1,000 hours to ensure sufficient stress exposure. Example structures (A, B, C) successfully passed the HTOL testing, demonstrating robust interconnect reliability suitable for long-term semiconductor device operation.

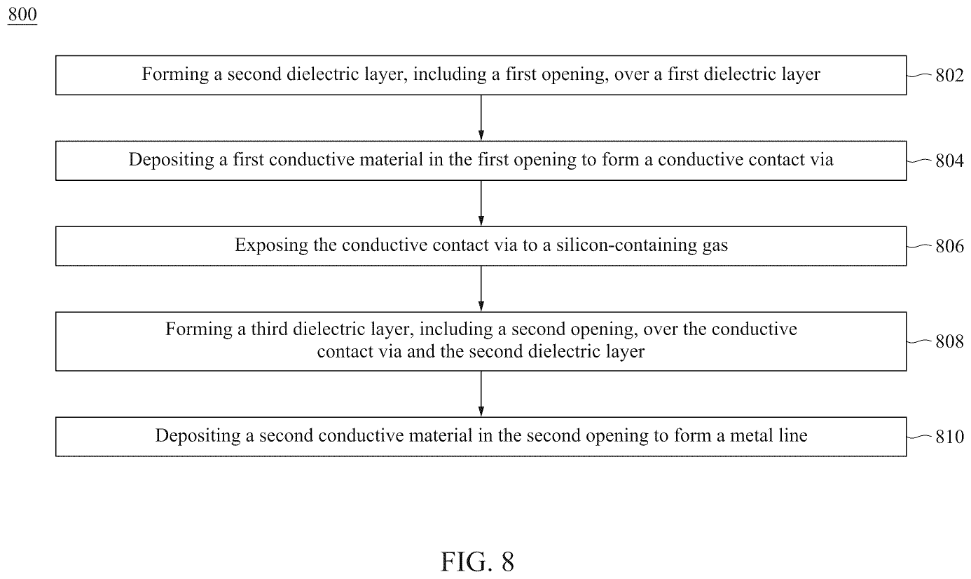

FIG. 8 is a flowchart of operations of a method 800 of manufacturing a semiconductor device 100, according to various embodiments. The method 800 includes performing processing operations (802, 804, 806, 808, 810) to form an interconnect structure (106b, 106c) over a plurality of transistors 106a, such that the interconnect structure (106b, 106c) includes a plurality of dielectric layers (118a, 118b, 118c) interleaved by a plurality of etch stop layers (124a, 124b), and the interconnect structure (106b, 106c) includes a plurality of metal lines 104 disposed in the plurality of dielectric layers (118a, 118b, 118c).

In operation 802, the method 800 includes forming a second dielectric layer 118b, including a first opening 501a, over a first dielectric layer 118a. In operation 804, the method 800 includes depositing a first conductive material (102a, 102b) in the first opening 501a to form a conductive contact via 102. In operation 806, the method 800 includes exposing the conductive contact via 102 to a silicon-containing gas. In operation 808, the method 800 includes forming a third dielectric layer 118c, including a second opening 501b, over the conductive contact via 102 and the second dielectric layer 118b. In operation 810, the method 800 includes depositing a second conductive material in the second opening 501b to form a metal line 104. According to various embodiments, depositing the first conductive material (102a, 102b) includes depositing at least one of W, Mo, or Ru, exposing the conductive contact via 102 also exposes the second dielectric layer 118b, and the silicon-containing gas includes a silane.

According to various embodiments, the method 800 further includes depositing a barrier layer 126 including a metal nitride layer before depositing the second conductive material. According to various embodiments, the conductive contact via 102 is barrier free. According to various embodiments, depositing the metal nitride layer includes depositing tantalum nitride. According to various embodiments, the method 800 further includes depositing a liner layer over the barrier layer 126 in the second opening 501b before depositing the second conductive material. According to various embodiments, depositing the liner layer includes depositing a layer of cobalt in the second opening 501b.

According to various embodiments, the method 800 further includes introducing a hydrogen plasma into the second opening 501b and performing a hydrogen plasma etch process before depositing the second conductive material. According to various embodiments, depositing the second conductive material includes depositing Cu in the second opening 501b. According to various embodiments, exposing the conductive contact via 102 to the silicon-containing gas further includes generating a silicon concentration gradient along the conductive contact via 102 that decreases from a top of the conductive contact via 102 to a bottom of the conductive contact via 102. According to various embodiments, the method 800 further includes performing a planarization operation 508 on a top surface of the conductive contact via 102 and the second dielectric layer 118b before exposing the conductive contact via 102 and the second dielectric layer 118b to the silicon-containing gas.

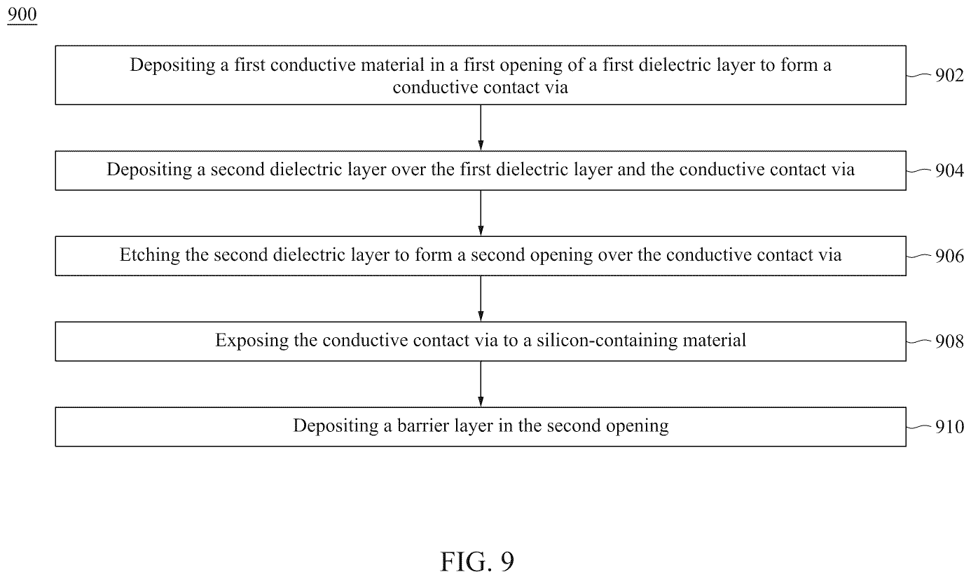

FIG. 9 is a flowchart of operations of a method 900 of manufacturing a semiconductor device 100, according to various embodiments. The method 900 includes performing process operations (902, 904, 906, 908, 910) to form an interconnect structure (106b, 106c) that is electrically connected to a transistor structure 106a. In operation 902, the method 900 includes depositing a first conductive material (102a, 102b) in a first opening 501a of a first dielectric layer 118b to form a conductive contact via 102. In operation 902, the method 900 includes depositing a second dielectric layer 118c over the first dielectric layer 118b and the conductive contact via 102. In operation 904, the method 900 includes etching the second dielectric layer 118b to form a second opening 501b over the conductive contact via 102. In operation 906, the method 900 includes exposing the conductive contact via 102 to a silicon-containing material.

In operation 908, the method 900 includes depositing a barrier layer 126 in the second opening 501b.

According to various embodiments, the transistor structure 106a includes a source/drain feature 114, a contact etch stop layer 120 disposed over the source/drain feature 114, an interlayer dielectric layer 118a disposed over the contact etch stop layer 120, and a source/drain contact 122 disposed in the interlayer dielectric layer 118a to electrically couple to the source/drain feature 114. According to various embodiments, depositing the first conductive material (102a, 102b) includes depositing at least one of W, Mo, or Ru. According to various embodiments, exposing the conductive contact via 102 to the silicon-containing material includes depositing a silicon-containing self-assembled monolayer 601 over the conductive contact via 102 by exposing a top surface of the conductive contact via 102 to a layer of dodecyl silane. According to various embodiments, the dodecyl silane is a liquid. According to various embodiments, exposing the conductive contact via 102 to the silicon-containing material includes exposing the conductive contact via 102 to a silicon-containing gas.

According to various embodiments, removing the silicon-containing self-assembled monolayer 601 includes introducing a hydrogen plasma into the second opening 501b after forming the barrier layer 126, such that the hydrogen plasma removes a remaining portion of the silicon-containing self-assembled monolayer 601. According to various embodiments, the method 900 further includes depositing a Cu fill layer in the second opening 501b over the barrier layer 126 to form a metal line 104 that forms an electrically conductive contact with the conductive contact via 102.

Referring to all drawings and according to various embodiments of the instant disclosure a semiconductor device 100 is disclosed. The semiconductor device 100 includes a transistor structure 106a and an electrical contact structure (102, 104, 122). The transistor structure 106a includes an active region 108 over a substrate, a gate structure (110, 112) including a gate dielectric layer 112 over the active region 108 and a gate electrode over the gate dielectric layer 112, a gate spacer 116 extending along a sidewall of the gate structure (110, 112), wherein a dielectric constant of the gate dielectric layer 112 is greater than a dielectric constant of the gate spacer 116, and a source/drain contact 122.

The electrical contact structure (102, 104, 122) includes a conductive contact via 102 formed in a first dielectric layer 118a and electrically contacting the source/drain contact 122, a metal line 104 formed in a second dielectric layer 118b, such that the metal line 104 forms an electrically conductive contact with the conductive contact via 102, and a first metal-silicide layer 128a formed between the conductive contact via 102 and the first dielectric layer 118a and extending from a top surface of the conductive contact via 102 to a depth H2 that is less than a depth H1 of the conductive contact via 102 measured from the top surface of the conductive contact via 102.

According to various embodiments, the semiconductor device 100 further includes a second metal-silicide layer 128b formed between the conductive contact via 102 and the metal line 104. According to various embodiments, the metal line 104 includes Cu, and the first metal-silicide layer 128a and the second metal-silicide layer 128b include a copper silicide. According to various embodiments, the conductive contact via 102 includes at least one of W, Mo, or Ru.

Disclosed embodiments advantageously provide conductive contacts (102, 104) that exhibit reduced contact resistance Rc and reduced undesirable material interactions, such as short circuits, which could otherwise degrade device performance. In this regard, disclosed electrical contacts (102, 104) include metal-silicide layers (128a, 128b) formed at metal/metal and metal/dielectric interfaces. The presence of the metal-silicide layers (128a, 128b) advantageously prevents Cu diffusion and ensures a low contact resistance between metal/metal interfaces.

According to various embodiments, a method of manufacturing a semiconductor device includes performing processing operations to form an interconnect structure over a plurality of transistors, such that the interconnect structure includes a plurality of dielectric layers interleaved by a plurality of etch stop layers, and the interconnect structure includes a plurality of metal lines disposed in the plurality of dielectric layers. The processing operations include forming a second dielectric layer, including a first opening, over a first dielectric layer, depositing a first conductive material in the first opening to form a conductive contact via, exposing the conductive contact via to a silicon-containing gas, forming a third dielectric layer, including a second opening, over the conductive contact via and the second dielectric layer, and depositing a second conductive material in the second opening to form a metal line.

According to various embodiments, depositing the first conductive material includes depositing at least one of W, Mo, or Ru, exposing the conductive contact via also exposes the second dielectric layer, and the silicon-containing gas includes a silane. According to various embodiments, the method further includes depositing a barrier layer including a metal nitride layer before depositing the second conductive material. According to various embodiments, the conductive contact via is barrier free. According to various embodiments, depositing the metal nitride layer includes depositing tantalum nitride. According to various embodiments, the method further includes depositing a liner layer over the barrier layer in the second opening before depositing the second conductive material. According to various embodiments, depositing the liner layer includes depositing a layer of cobalt in the second opening.

According to various embodiments, the method further includes introducing a hydrogen plasma into the second opening and performing a hydrogen plasma etch process before depositing the second conductive material. According to various embodiments, depositing the second conductive material includes depositing Cu in the second opening. According to various embodiments, exposing the conductive contact via to the silicon-containing gas further includes generating a silicon concentration gradient along the conductive contact via that decreases from a top of the conductive contact via to a bottom of the conductive contact via. According to various embodiments, the method further includes performing a planarization operation on a top surface of the conductive contact via and the second dielectric layer before exposing the conductive contact via and the second dielectric layer to the silicon-containing gas.

According to various embodiments, a method of method of manufacturing a semiconductor device includes performing process operations to form an interconnect structure that is electrically connected to a transistor structure. The process operations include depositing a first conductive material in a first opening of a first dielectric layer to form a conductive contact via, depositing a second dielectric layer over the first dielectric layer and the conductive contact via, etching the second dielectric layer to form a second opening over the conductive contact via, exposing the conductive contact via to a silicon-containing material, and depositing a barrier layer in the second opening. According to various embodiments, the transistor structure includes a source/drain feature, a contact etch stop layer disposed over the source/drain feature, an interlayer dielectric layer disposed over the contact etch stop layer, and a source/drain contact disposed in the interlayer dielectric layer to electrically couple to the source/drain feature.

According to various embodiments, depositing the first conductive material includes depositing at least one of W, Mo, or Ru. According to various embodiments, exposing the conductive contact via to the silicon-containing material includes depositing a silicon-containing self-assembled monolayer over the conductive contact via by exposing a top surface of the conductive contact via to a layer of dodecyl silane. According to various embodiments, the dodecyl silane is a liquid. According to various embodiments, exposing the conductive contact via to the silicon-containing material includes exposing the conductive contact via to a silicon-containing gas.

According to various embodiments, method removing the silicon-containing self-assembled monolayer includes introducing a hydrogen plasma into the second opening after forming the barrier layer, such that the hydrogen plasma removes a remaining portion of the silicon-containing self-assembled monolayer. According to various embodiments, the method further includes depositing a Cu fill layer in the second opening over the barrier layer to form a metal line that forms an electrically conductive contact with the conductive contact via.

According to various embodiments, a semiconductor device includes a transistor structure including an electrical contact structure. The transistor structure includes an active region over a substrate, a gate structure including a gate dielectric layer over the active region and a gate electrode over the gate dielectric layer, a gate spacer extending along a sidewall of the gate structure, wherein a dielectric constant of the gate dielectric layer is greater than a dielectric constant of the gate spacer, and a source/drain contact. The electrical contact structure includes a conductive contact via formed in a first dielectric layer and electrically contacting the source/drain contact, a metal line formed in a second dielectric layer, such that the metal line forms an electrically conductive contact with the conductive contact via, and a first metal-silicide layer formed between the conductive contact via and the first dielectric layer and extending from a top surface of the conductive contact via to a depth that is less than a depth of the conductive contact via measured from the top surface of the conductive contact via.

According to various embodiments, the semiconductor device further includes a second metal-silicide layer formed between the conductive contact via and the metal line. According to various embodiments, the metal line includes Cu, and the first metal-silicide layer and the second metal-silicide layer include a copper silicide. According to various embodiments, the conductive contact via includes at least one of W, Mo, or Ru.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A method of manufacturing a semiconductor device, comprising:
performing processing operations to form an interconnect structure over a plurality of transistors, wherein the interconnect structure comprises a plurality of dielectric layers interleaved by a plurality of etch stop layers, and the interconnect structure comprises a plurality of metal lines disposed in the plurality of dielectric layers, the processing operations comprising:
forming a second dielectric layer, comprising a first opening, over a first dielectric layer;
depositing a first conductive material in the first opening to form a conductive contact via;
exposing the conductive contact via to a silicon-containing gas;
forming a third dielectric layer, comprising a second opening, over the conductive contact via and the second dielectric layer; and
depositing a second conductive material in the second opening to form a metal line.

2. The method of claim 1, wherein:
depositing the first conductive material comprises depositing at least one of W, Mo, or Ru;
exposing the conductive contact via also exposes the second dielectric layer; and
the silicon-containing gas comprises a silane.

3. The method of claim 1, further comprising depositing a barrier layer comprising a metal nitride layer before depositing the second conductive material,
wherein the conductive contact via is barrier free.

4. The method of claim 3, wherein depositing the metal nitride layer comprises depositing tantalum nitride.

5. The method of claim 3, further comprising depositing a liner layer over the barrier layer in the second opening before depositing the second conductive material.

6. The method of claim 5, wherein depositing the liner layer comprises depositing a layer of cobalt in the second opening.

7. The method of claim 1, further comprising:
introducing a hydrogen plasma into the second opening and performing a hydrogen plasma etch process before depositing the second conductive material,
wherein depositing the second conductive material comprises depositing Cu in the second opening.

8. The method of claim 1, wherein exposing the conductive contact via to the silicon-containing gas further comprises generating a silicon concentration gradient along the conductive contact via that decreases from a top of the conductive contact via to a bottom of the conductive contact via.

9. The method of claim 1, further comprising:
performing a planarization operation on a top surface of the conductive contact via and the second dielectric layer before exposing the conductive contact via and the second dielectric layer to the silicon-containing gas.

10. A method of manufacturing a semiconductor device, comprising:
performing process operations to form an interconnect structure that is electrically connected to a transistor structure, the process operations comprising:
depositing a first conductive material in a first opening of a first dielectric layer to form a conductive contact via;
depositing a second dielectric layer over the first dielectric layer and the conductive contact via;
etching the second dielectric layer to form a second opening over the conductive contact via;
exposing the conductive contact via to a silicon-containing material; and
depositing a barrier layer in the second opening,
wherein the transistor structure comprises:
a source/drain feature;
a contact etch stop layer disposed over the source/drain feature;
an interlayer dielectric layer disposed over the contact etch stop layer; and
a source/drain contact disposed in the interlayer dielectric layer to electrically couple to the source/drain feature.

11. The method of claim 10, wherein depositing the first conductive material comprises depositing at least one of W, Mo, or Ru.

12. The method of claim 10, wherein exposing the conductive contact via to the silicon-containing material comprises depositing a silicon-containing self-assembled monolayer over the conductive contact via by exposing a top surface of the conductive contact via to a layer of dodecyl silane.

13. The method of claim 12, wherein the dodecyl silane is a liquid.

14. The method of claim 10, wherein exposing the conductive contact via to the silicon-containing material comprises exposing the conductive contact via to a silicon-containing gas.

15. The method of claim 12, further comprising removing the silicon-containing self-assembled monolayer, comprises introducing a hydrogen plasma into the second opening after forming the barrier layer, such that the hydrogen plasma removes a remaining portion of the silicon-containing self-assembled monolayer.

16. The method of claim 10, further comprising:
depositing a Cu fill layer in the second opening over the barrier layer to form a metal line that forms an electrically conductive contact with the conductive contact via.

17. A semiconductor device, comprising:
a transistor structure comprising:
an active region over a substrate;
a gate structure comprising a gate dielectric layer over the active region and a gate electrode over the gate dielectric layer; a gate spacer extending along a sidewall of the gate structure, wherein a dielectric constant of the gate dielectric layer is greater than a dielectric constant of the gate spacer; and
a source/drain contact; and
an electrical contact structure, comprising:
a conductive contact via formed in a first dielectric layer and electrically contacting the source/drain contact;
a metal line formed in a second dielectric layer, such that the metal line forms an electrically conductive contact with the conductive contact via; and
a first metal-silicide layer formed between the conductive contact via and the first dielectric layer and extending from a top surface of the conductive contact via to a depth that is less than a depth of the conductive contact via measured from the top surface of the conductive contact via.

18. The semiconductor device of claim 17, further comprising:
a second metal-silicide layer formed between the conductive contact via and the metal line.

19. The semiconductor device of claim 18, wherein:
the metal line comprises Cu; and
the first metal-silicide layer and the second metal-silicide layer comprise a copper silicide.

20. The semiconductor device of claim 17, wherein the conductive contact via comprises at least one of W, Mo, or Ru.
